(19) United States
(12) Patent Application Publication
(10) Pub. No.: US 2026/0247960 A1
(43) Pub. Date: Aug. 20, 2026

(54) INDUCTOR FOR SEMICONDUCTOR PACKAGE

(71) Applicant: TEXAS INSTRUMENTS INCORPORATED, DALLAS, TX (US)

(72) Inventors: JONATHAN ANDREW MONTOYA, DALLAS, TX (US); THIES PUCHERT, LANGENBACH (DE); ANTON WINKLER, KIRCHDORF AN DER AMPER (DE)

(21) Appl. No.: 19/057,299

(22) Filed: Feb. 19, 2025

(51) Int. Cl. H01L 23/522; H01F 17/00; H01L 23/64

(52) U.S. Cl. CPC H10W 20/497; H01F 17/0006; H10W 44/501; H01F 2017/0066

(57) ABSTRACT

A semiconductor package includes an interconnect having a mounting surface and a conductive inductor structure mounted on the interconnect. The conductive inductor structure includes a first leg region with a first bar extending orthogonally from the mounting surface to a given height and a first solderable member soldered to and extending parallel to the mounting surface. A second leg region includes a second bar extending orthogonally to the given height and a second solderable member soldered to and extending parallel to the mounting surface. A connecting bar extends at the given height between the first and second bars. A magnetic mold compound encases the conductive inductor structure to form an inductor.

### TECHNICAL FIELD

This description relates to a semiconductor package with an inductor.

### BACKGROUND

Inductors are used in semiconductor packages (e.g., IC (integrated circuit chips), providing critical functionality for power management and signal processing applications. Conventional inductor designs often employ significant package space and face challenges in maintaining consistent performance while meeting increasingly demanding power requirements. Recent advances in MMC (magnetic mold compound) technology have enabled the integration of inductor structures directly within semiconductor packages, allowing for more compact and efficient designs. These integrated inductors typically operate in the low inductance range (below 500 nanohenries) while handling substantial currents (up to 100 amperes) in modern power management applications. The inductor structures are formed using precisely shaped conductive elements that, when encased in magnetic mold compound, create the desired inductive properties. This approach to inductor integration represents an advancement in semiconductor packaging technology, particularly for applications needing high current handling capability in space-constrained environments.

MMC is a specialized material used in the manufacturing of magnetic components, such as transformers, inductors and motors. In some examples, MMC is a composite of magnetic powder and a polymer binder, designed to provide both magnetic properties and the flexibility needed for molding complex shapes. The magnetic powder, often composed of materials like iron or ferrite, allows the MMC to efficiently conduct and concentrate magnetic fields. The polymer binder ensures that the MMC can be easily molded into precise geometries, offering advantages like reduced energy loss, improved thermal stability and enhanced performance in electronic devices. MMC is useful in applications where space efficiency and high-performance magnetic characteristics are needed.

### SUMMARY

A first example relates to a semiconductor package including an interconnect having a mounting surface and a conductive inductor structure mounted on the interconnect. The conductive inductor structure includes a first leg region with a first bar extending orthogonally from the mounting surface to a given height and a first solderable member soldered to the mounting surface. The first solderable member is connected to the first bar and extends parallel to the mounting surface of the interconnect. The second leg includes a second bar extending orthogonally from the mounting surface to the given height and a second solderable member soldered to the mounting surface. The second solderable member is connected to the second bar and extends parallel to the mounting surface of the interconnect. A connecting bar extends at the given height between the first bar of the first leg region and the second bar of the second leg region. The semiconductor package also includes a magnetic mold compound encasing the conductive inductor structure. The magnetic mold compound and the conductive inductor structure form an inductor.

A second example is related to a method of fabricating a semiconductor package, the method includes applying solder to selected locations on a mounting surface of an interconnect. The method also includes forming a conductive inductor structure. Forming the conductive inductor includes a first leg region having a first bar extending orthogonally from a base and a first solderable member connected to the first bar and configured to extend parallel to the mounting surface. The forming of the conductive inductor structure also includes forming a second leg region having a second bar extending orthogonally from the base and a second solderable member connected to the second bar and configured to extend parallel to the mounting surface. Forming the conductive inductor structure also includes forming a connecting bar between the first bar and the second bar. The method also includes mounting the conductive inductor structure on the interconnect by placing the first solderable member and the second solderable member in contact with the solder. The method includes reflowing the solder to form solder connections between the first solderable member and the second solderable member and the interconnect and encapsulating the conductive inductor structure in a magnetic mold compound to form an inductor.

### BRIEF DESCRIPTION OF THE DRAWINGS

FIG. 1 illustrates a first example of a semiconductor package that includes an integrated inductor.

FIG. 2 illustrates a second example of a semiconductor package that includes an integrated inductor.

FIG. 3 illustrates a third example of a semiconductor package that includes an integrated inductor.

FIG. 4 illustrates a fourth example of a semiconductor package that includes an integrated inductor.

FIGS. 5A-5C illustrate an example of components of a semiconductor package that includes an integrated inductor.

FIG. 6 illustrates an example of current flow in an inductor.

FIG. 7 illustrates an example of a graph that plots an inductance of inductors as a function of direct current.

FIG. 8 illustrates a flowchart of an example method for fabricating a semiconductor package.

### DETAILED DESCRIPTION

This description relates to a semiconductor package (e.g., an IC (integrated circuit) chip) that incorporates a conductive inductor structure mounted on an interconnect surface and encased in MMC (magnetic mold compound) to form an integrated inductor. The conductive structure utilizes geometric configurations such as I-shaped and T-shaped designs with solderable members having areas of at least 0.9 square millimeters (mm²) to provide mechanical stability during assembly. Vertical bars extend orthogonally from the mounting surface to a particular height (e.g., about 2-3 millimeters), with a connecting bar joining the leg regions at this height to allow clearance over other package components. The MMC provides magnetic properties while the conductive structure creates current paths capable of handling up to 100 amperes with current densities below critical thresholds. The geometric designs incorporate wide solderable members and multiple contact points that resist tipping during assembly, while butterfly structures with split outputs reduce parasitic effects. Manufacturing involves applying solder paste, forming and mounting the conductive structure, reflowing solder connections and encapsulating in MMC. The resultant inductors achieve about 30-80 nanohenries inductance with a resistance between about 1.6-2.0 milliohms (mΩ), enabling high-current power management applications in space-constrained packages. The design of the inductor addresses challenges of mechanical stability during assembly, current handling capability and efficient space utilization while maintaining manufacturability through simple bending operations.

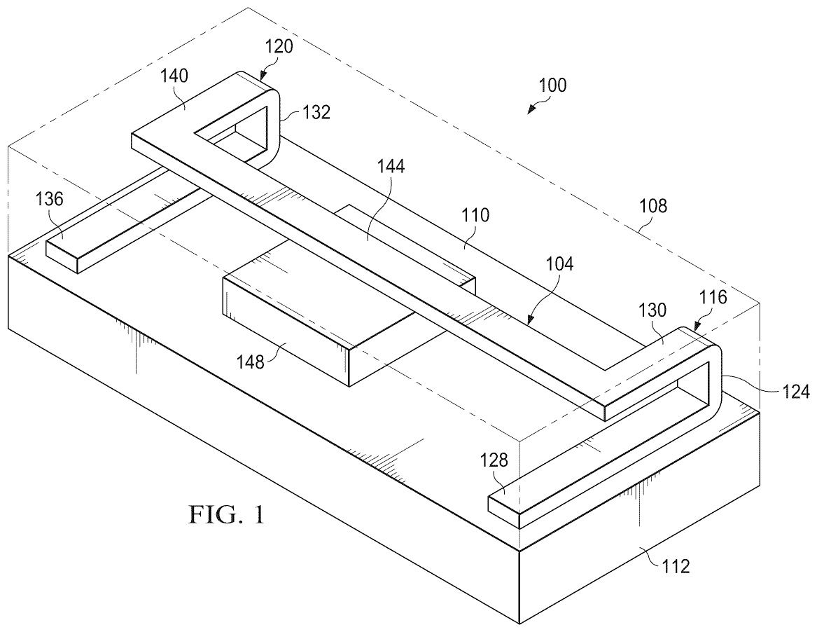

FIG. 1 illustrates a first example of a semiconductor package 100 (e.g., an IC chip) that includes an integrated inductor. The inductor is formed by a conductive inductor structure 104 encapsulated in an MMC 108 (magnetic mold compound). In the example illustrated, the conductive inductor structure 104 is an I-shaped conductive inductor structure 104, but in other examples, as explained herein, other shapes can be employed. The conductive inductor structure 104 is mounted on a mounting surface 110 (e.g., a top surface) of an interconnect 112, which can alternatively be referred to as a leadframe.

The conductive inductor structure 104 is formed of a malleable conductive material, such as copper (Cu) or another conductive material. The conductive inductor structure 104 includes a first leg region 116 and a second leg region 120. The first leg region 116 includes a first bar 124 that extends orthogonally from the mounting surface 110 of the interconnect 112 to a given height, such as about 2-3 millimeters (mm). The first leg region 116 also includes a first solderable member 128 that has a rectangular prism shape. The first solderable member 128 extends along the mounting surface 110 of the interconnect 112. The first solderable member 128 is connected to the first bar 124 of the first leg region 116. The first solderable member 128 has an area of about 0.9 square millimeters (mm²) or more. The first leg region 116 also includes a first tying region 130 connected to the first bar 124. In the example illustrated, the first tying region 130 extends parallel to the mounting surface 110 at the given height and overlays a portion of the first solderable member 128.

In the example illustrated in FIG. 1, the second leg region 120 is a mirror of the first leg region 116. Thus, the second leg region 120 includes a second bar 132 that extends orthogonally from the mounting surface 110 of the interconnect 112 to the given height. The second leg region 120 also includes a second solderable member 136 that extends along the mounting surface 110 and is connected to the second bar 132. The second solderable member 136 has a rectangular prism shape and a solderable area of about 9 square millimeters (mm²) or more. The second leg region 120 also includes a second tying region 140 connected to the second bar 132.

The conductive inductor structure 104 includes a connecting bar 144 that extends between the first leg region 116 and the second leg region 120. More specifically, the connecting bar 144 is connected to the first tying region 130 of the first leg region 116 and the second tying region 140 of the second leg region 120. The connecting bar 144 has a length, for example, of about 5 to about 10 millimeters (mm). The connecting bar extends parallel to the mounting surface 110 of the interconnect 112 at the given height. Moreover, in the example illustrated, the connecting bar 144 overlays a component 148 mounted on the mounting surface 110 of the interconnect 112. The component 148 can represent a circuit component, such as a passive circuit component or a semiconductor component. Moreover, the component 148 represents multiple circuit components in some examples. The given height is selected to be taller than component 148. Because the connecting bar 144 extends at the given height, the connecting bar 144 does not contact the component 148. In the example illustrated, the first solderable member 128 and the second solderable member 136 are parallel.

The MMC 108 encapsulates the conductive inductor structure 104 to provide the inductor for the semiconductor package 100. The inductor has an inductance, for example of at least 30 millihenries (mH), and in some examples, the conductive inductor structure 104 can be sized to have a maximum current of about 100 amperes (A). Further, in various examples, the semiconductor package 100 and/or the conductive inductor structure 104 can be sized to provide different operating characteristics. In the example illustrated in FIG. 1, the first leg region 116 and the second leg region 120 are arranged symmetrically on opposite sides of a center axis of the connecting bar 144, and the first bar 124 and the second bar 132 are parallel to each other and extend orthogonally from the mounting surface 110. In other examples, other arrangements are possible.

The MMC 108 encases the conductive inductor structure 104 to form an inductor. The first solderable member 128 and the second solderable member 136 provide stable mechanical mounting during assembly while enabling high current operation over the intended product lifetime. In operation, the MMC 108 provides the magnetic properties required for inductor operation, while the conductive inductor structure 104 provides the current path. The first solderable member 128 and the second solderable member 136 are sized with sufficient area to maintain current density below a predetermined threshold (e.g., less than 100 A/mm² in one example) that reduces electromigration risk. In summary, the relatively large footprint provided by the first solderable member 128 and the second solderable member 136 increases mechanical stability during soldering of the conductive inductor structure 104 to the interconnect 112 and curtails risk of electromigration at the solder interfaces of the conductive inductor structure 104.

More specifically. the I-shaped conductive inductor structure 104 design enables stable mounting during assembly by providing the solderable members 128, 136 with a wide footprint that resist tipping before reflow. The conductive inductor structure 104 design ensures efficient use of package space by extending the connecting bar 144 over the component 148 (which can represent multiple components). Additionally, the large solderable areas of the first solderable member 128 and the second solderable member 136 reduce current density to enable current handling up to approximately 100 amperes while maintaining acceptable lifetime reliability. Furthermore, the I-shaped design of the conductive inductor structure 104 offers manufacturing simplicity through minimal bending operations (e.g., bending from a base that includes the connecting bar 144) during formation of the conductive structure.

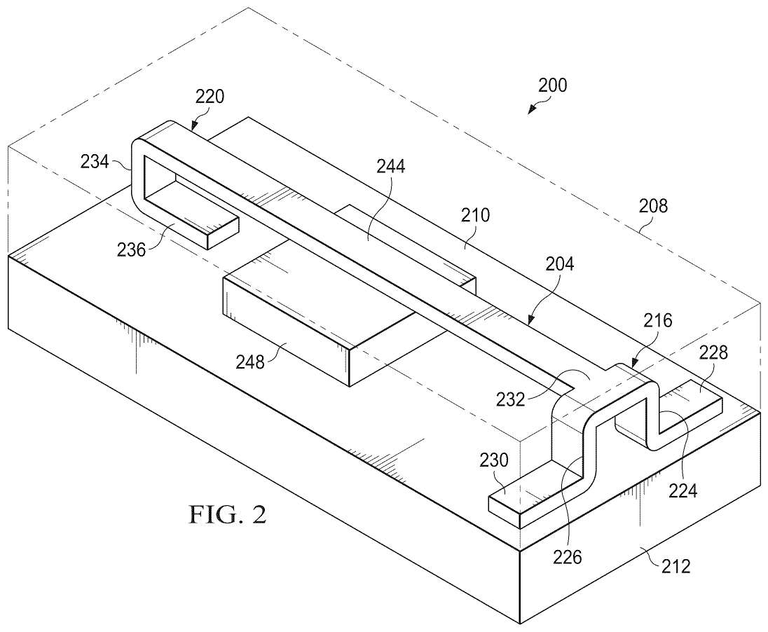

FIG. 2 illustrates a second example of a semiconductor package 200 that includes an integrated inductor. The inductor is formed by a conductive inductor structure 204 encapsulated in a MMC 208 (magnetic mold compound). The conductive inductor structure 204 is a T-shaped conductive inductor structure mounted on a mounting surface 210 of an interconnect 212.

The conductive inductor structure 204 includes a first leg region 216 and a second leg region 220. The first leg region 216 includes a first bar 224 and a second bar 226 that extend orthogonally from the mounting surface 210 to a given height. The first leg region 216 includes a first solderable member 228 and a second solderable member 230 having a rectangular prism shape that extend along the mounting surface 210. The first leg region 216 also includes a first tying region 232 connected to the first bar 224 and the second bar 226. The first leg region 216 has an inverted U-shaped cross section.

The second leg region 220 includes a third bar 234 that extends orthogonally from the mounting surface 210 to the given height. The second leg region 220 includes a third solderable member 236 that extends along the mounting surface 210 and connects to the third bar 234. The second solderable member 236 has a rectangular prism shape.

The conductive inductor structure 204 includes a connecting bar 244 that extends between the first leg region 216 and the second leg region 220. The connecting bar 244 extends parallel to the mounting surface 210 at the given height. The connecting bar 244 overlays a component 248 mounted on the mounting surface 210 between the first leg region 216 and the second leg region 220. The MMC 208 encapsulates the conductive inductor structure 204 to form an inductor. The resultant inductor has an inductance of at least 30 millihenries (mH), and the conductive inductor structure 204 handles currents up to about 100 A.

The T-shaped conductive inductor structure 204 is a “butterfly” structure with split outputs that reduces parasitic effects and ground bounce by dividing current flow. Stated differently, in operation, the third solderable member 236 is an input for the inductor and the first solderable member 228 and the second solderable member 230 are outputs for the inductor, and in some examples, the first solderable member 228 and the second solderable member 230 are coupled (e.g., with an electrical trace on the interconnect 212). The shape of the conductive inductor structure 204 efficiently uses package space by extending the connecting bar 244 over the component 248. The first leg region 216 with the first bar 224 and the second bar 226 provides enhanced mechanical stability during assembly. Additionally, the large solderable areas of the first solderable member 228, the second solderable member 230 and the third solderable member 236 (e.g., about 0.9 mm² in some examples) reduce current density to enable high current handling while maintaining reliability. The T-shaped design offers manufacturing simplicity through minimal bending (e.g., bending from a base that includes the connecting bar 244) operations during formation. In summary, the relatively large footprint provided by the first solderable member 228 and the second solderable member 230 of the first leg region 216 as well as the third solderable member 236 of the second leg region 220 increases mechanical stability during soldering of the conductive inductor structure 204 to the interconnect 212 and curtails risk of electromigration at the solder interfaces of the conductive inductor structure 204.

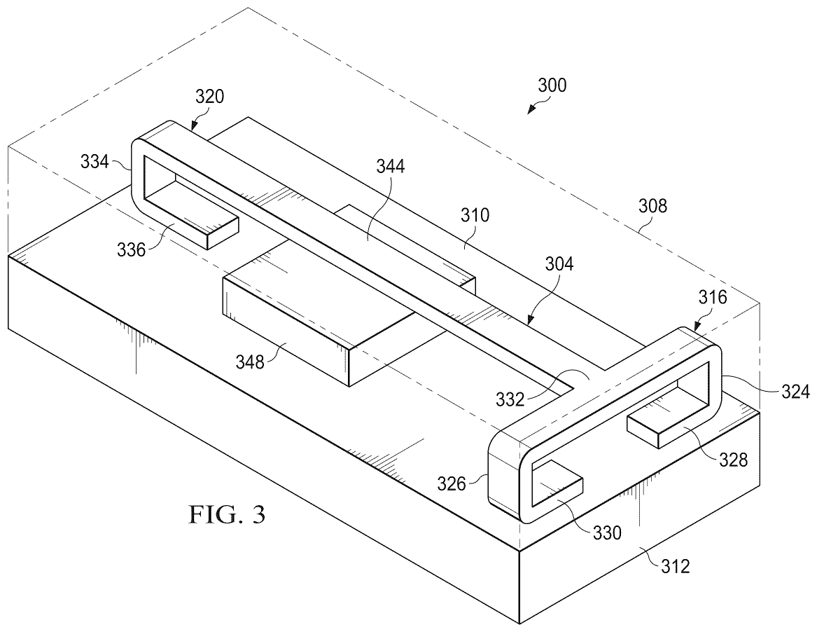

FIG. 3 illustrates a third example of a semiconductor package 300 that includes an integrated inductor. The inductor is formed by a conductive inductor structure 304 encapsulated in a MMC 308 (magnetic mold compound). The conductive inductor structure 304 is mounted on a mounting surface 310 of an interconnect 312.

The conductive inductor structure 304 includes a first leg region 316 and a second leg region 320. The first leg region 316 includes a first bar 324 and a second bar 326 that extend orthogonally from the mounting surface 310 to a given height. The first leg region 316 includes a first solderable member 328 and a second solderable member 330 having rectangular prism shapes that extend along the mounting surface 310. The first solderable member 328 and the second solderable member 330 are spaced apart from each other. The first leg region 316 also includes a first tying region 332 connected to the first bar 324 and the second bar 326. The first leg region 316 has a C-shaped cross-section (in at least one orientation).

The second leg region 320 includes a third bar 334 that extends orthogonally from the mounting surface 310 to the given height. The second leg region 320 includes a third solderable member 336 that extends along the mounting surface 310 and connects to the third bar 334. The third solderable member 336 has a rectangular prism shape.

The conductive inductor structure 304 includes a connecting bar 344 that extends between the first leg region 316 and the second leg region 320. The connecting bar 344 extends parallel to the mounting surface 310 at the given height. The connecting bar 344 overlays a component 348 mounted on the mounting surface 310 between the first leg region 316 and the second leg region 320. The connecting bar 344 has a length, for example, of about 5 to about 10 millimeters (mm).

The T-shaped conductive inductor structure 304 provides several advantages. The design provides another butterfly structure with split outputs that reduces parasitic effects and ground bounce by dividing current flow between the first solderable member 328 and the second solderable member 330. The shape efficiently uses package space by extending the connecting bar 344 over the component 348. The first leg region 316 with dual bars 324, 326 provides enhanced mechanical stability during assembly. Additionally, the large solderable areas of members 328, 330, 336 (each about 0.9 mm²) reduce current density to enable high current handling up to 100 amperes while maintaining reliability. The T-shaped design offers manufacturing simplicity through minimal bending operations (e.g., bending from a base that includes the connecting bar 344) during formation.

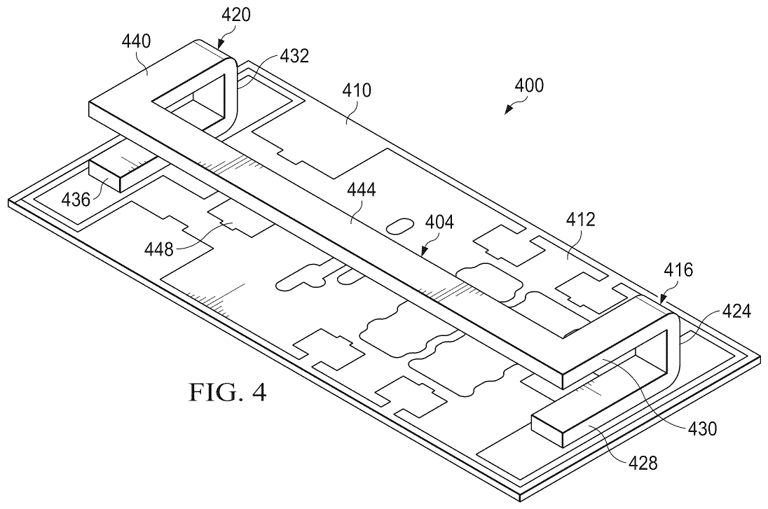

FIG. 4 illustrates a fourth example of a semiconductor package 400 (e.g., an IC chip) that includes an integrated inductor. The inductor is formed by a conductive inductor structure 404 encapsulated in an MMC (not shown). In the example illustrated, the conductive inductor structure 404 is an I-shaped conductive inductor structure 404, but in other examples, as explained herein, other shapes can be employed. The conductive inductor structure 404 is mounted on a mounting surface 410 (e.g., a top surface) of an interconnect 412, which can alternatively be referred to as a leadframe.

The conductive inductor structure 404 is formed of a malleable conductive material and includes a first leg region 416 and a second leg region 420. The first leg region 416 includes a first bar 424 that extends orthogonally from the mounting surface 410 of the interconnect 412 to a given height, such as about 2-3 millimeters (mm). The first leg region 416 also includes a first solderable member 428 that has a rectangular prism shape. The first solderable member 428 extends along the mounting surface 410 of the interconnect 412. The first solderable member 428 is connected to the first bar 424 of the first leg region 416. The first solderable member 428 has an area of about 0.9 square millimeters (mm²) or more. The first leg region 416 also includes a first tying region 430 connected to the first bar 424. In the example illustrated, the first tying region 430 extends parallel to the first solderable member 428 at the given height and overlays the first solderable member 428.

In the example illustrated in FIG. 4, the second leg region 420 is a mirror of the first leg region 416. Thus, the second leg region 420 includes a second bar 432 that extends orthogonally from the mounting surface 410 of the interconnect 412 to the given height. The second leg region 420 also includes a second solderable member 436 that extends along the mounting surface 410 and is connected to the second bar 432. The second solderable member 436 has a rectangular prism shape and a solderable area of about 9 square millimeters (mm²) or more. The second leg region 420 also includes a second tying region 440 connected to the second bar 432.

The conductive inductor structure 404 includes a connecting bar 444 that extends between the first leg region 416 and the second leg region 420. More specifically, the connecting bar 444 is connected to the first tying region 430 of the first leg region 416 and the second tying region 440 of the second leg region 420, with a length of about 5 mm to about 10 mm. The connecting bar 444 extends parallel to the mounting surface 410 of the interconnect 412 at the given height. Moreover, in the example illustrated, the connecting bar 444 overlays a component 448 mounted on the mounting surface 410 of the interconnect 412. The component 448 can represent a circuit component, such as a passive circuit component or a semiconductor component. Moreover, the component 448 represents multiple circuit components in some examples. The given height is selected to be taller than component 448. Because the connecting bar 444 extends at the given height, the connecting bar 444 does not contact the component 448. In the example illustrated, the first solderable member 428 and the second solderable member 436 are parallel.

The MMC encapsulates the conductive inductor structure 404 to provide the inductor for the semiconductor package 400. The inductor has an inductance, for example of at least 30 millihenries (mH), and in some examples, the conductive inductor structure 404 can be sized to have a maximum current of about 400 amperes (A). Further, in various examples, the semiconductor package 400 and/or the conductive inductor structure 404 can be sized to provide different operating characteristics. In the example illustrated in FIG. 4, the first leg region 416 and the second leg region 420 are arranged asymmetrically relative to a center axis of the connecting bar 444, and the first bar 424 and the second bar 432 are parallel to each other and extend orthogonally from the mounting surface 410. The asymmetric arrangement of FIG. 4 enables the connecting bar 444 to avoid contact with particular components that may be mounted on the mounting surface 410. In other examples, other arrangements are possible.

The first solderable member 428 and the second solderable member 436 provide stable mechanical mounting during assembly while enabling high current operation over the intended product lifetime. In operation, the magnetic mold compound provides the magnetic properties required for inductor operation, while the conductive inductor structure 404 provides the current path. The first solderable member 428 and the second solderable member 436 are sized with sufficient area to maintain current density below a predetermined threshold (e.g., less than 400 A/mm² in one example) that reduces electromigration risk.

The I-shaped conductive inductor structure 404 design enables stable mounting during assembly by providing wide solderable members 428, 436 that resist tipping before reflow. The conductive inductor structure 404 design ensures efficient use of package space by extending the connecting bar 444 over the component 448 (which can represent multiple components). Additionally, the large solderable areas of the first solderable member 428 and the second solderable member 436 reduce current density to enable current handling up to approximately 400 amperes while maintaining acceptable lifetime reliability. Furthermore, the I-shaped design of the conductive inductor structure 404 offers manufacturing simplicity through minimal bending (e.g., benign from a base that includes the connecting bar 444) operations during formation of the conductive structure.

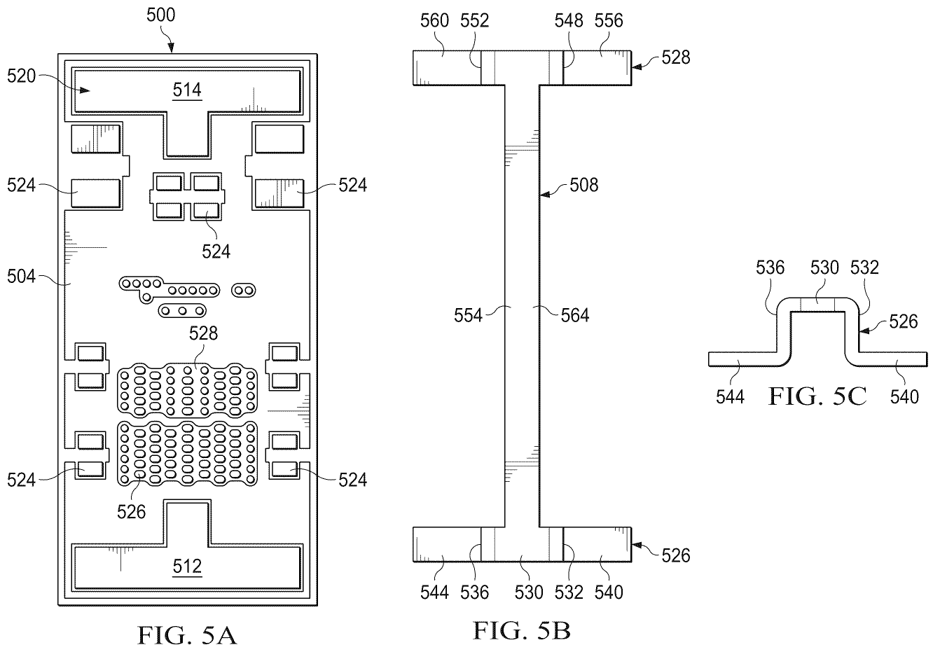

FIGS. 5A-5C illustrates an example of components of a semiconductor package that includes an integrated inductor. More specifically, FIG. 5A illustrates an example of an interconnect 500 with a mounting surface 504. The interconnect 500 receives a conductive inductor structure 508 that is illustrated in FIG. 5B. The mounting surface 504 includes a first mounting pad 512 and a second mounting pad 514 for receiving the conductive inductor structure. Landing pads 524 (e.g., solder pads) for circuit components (only some of which are labeled) that are mountable on the mounting surface of the interconnect.

Referring to FIG. 5B, the inductor is formed by a conductive inductor structure 508 encapsulated in a MMC (not shown). The conductive inductor structure 508 is mounted on (e.g., soldered to) the first mounting pad 512 and the second mounting pad 514 of the interconnect 500 of FIG. 1.

The conductive inductor structure 508 includes a first leg region 526 and a second leg region 528. The first leg region 516 includes a first bar 532 and a second bar 536 that extend orthogonally from the mounting surface 504 of FIG. 5A to a given height. The first leg region 516 includes a first solderable member 540 and a second solderable member 544 that are spaced apart from each other, have rectangular prism shapes, and extend along the mounting surface 504 of FIG. 5A. The first leg region 526 also includes a first tying region 530 connected to the first bar 532 and the second bar 536.

The second leg region 528 includes a third bar 548 and a fourth bar 552 that extend orthogonally from the mounting surface 504 (of FIG. 5A) to the given height. The second leg region 520 includes a third solderable member 556 and a fourth solderable member 560 that extend along the mounting surface 504. The third solderable member 556 connects to the third bar 548 and the fourth solderable member 560. The third solderable member 556 and the fourth solderable member 560 have a rectangular prism shape.

The conductive inductor structure 508 includes a connecting bar 564 that extends between the first leg region 526 and the second leg region 528. The connecting bar 564 extends parallel to the mounting surface 504 of FIG. 5A at the given height. The connecting bar 564 overlays a portion of the components mounted on the landing pads 524 of FIG. 5A mounted on the mounting surface 504 between the first leg region 516 and the second leg region 520.

FIG. 5C illustrates a cross-sectional view of the first leg region 526. As illustrated, the first leg region 526 has an inverted-U shape. The cross-sectional view of the second leg region 528 would look the same.

Viewed together, FIGS. 5A-5C illustrate that the shaped conductive inductor structure 508 provides several advantages. The design provides split inputs and split outputs that reduces parasitic effects and ground bounce by dividing current flow between the first solderable member 540 and the second solderable member 544 on an output of the inductor as well as the third solderable member 556 and the fourth solderable member 560 on the input of the inductor. The shape efficiently uses package space by extending the connecting bar 554 over the components mounted on the landing pads 524, with a length of about 5 mm to about 10 mm. The first leg region 526 with the first bar 532 and the second bar 536, as well as the second leg region 528 with the third bar 548 and the fourth bar 552 provides enhanced mechanical stability during assembly. Additionally, the large solderable areas of members 540, 544, 556 and 560 (each about 0.9 mm²) reduce current density to enable high current handling up to 100 amperes while maintaining reliability.

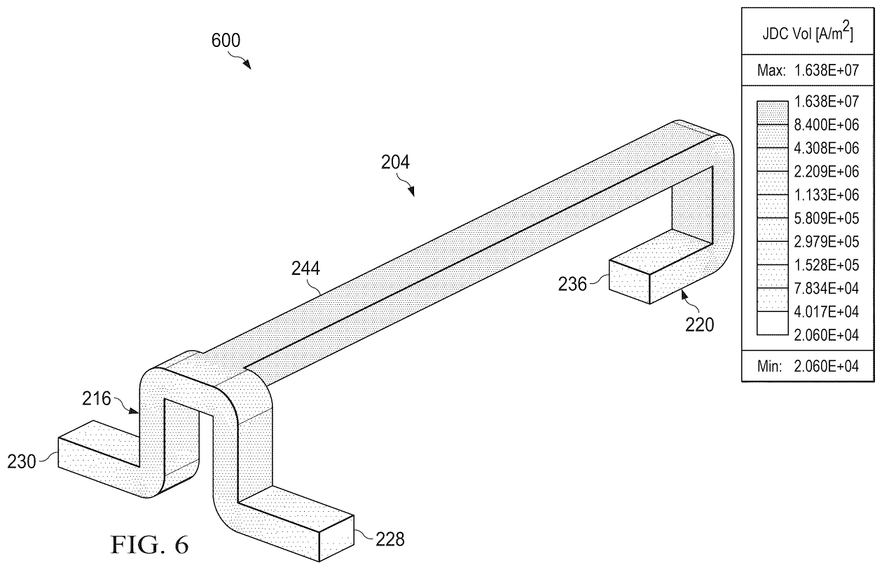

FIG. 6 illustrates an example of current flow in an inductor 600 illustrating a current density visualization with a grey scale ranging from approximately 2.060E+04 (minimum) to 1.638E+7 (maximum) amperes per square meter (A/m²). For simplification the inductor 600 corresponds to the conductive inductive structure 204 of FIG. 2, and thus employs the same reference numbers. The visualization depicts current flowing from a second leg region 220, through a connecting bar 244 to a first leg region 216 and to components (not shown) that are coupled to the first leg region 216. The current flow pattern demonstrates how the relatively large surface area of the solderable members in the first leg region 216 and the second leg region 220 helps distribute the current and reduce current density. The gradient shows higher current density along the connecting bar 244 transitioning to lower current density as the current spreads through the conductive inductor structure 204 and near the connection regions on the first leg region 216, such as the first solderable member 228 and the second solderable member 230, as well as the second leg region 220 that includes the third solderable member 236. This current distribution pattern helps maintain current density below predetermined thresholds to curtail electromigration issues while enabling high current operation. The visualization specifically demonstrates how the butterfly structure at the first leg region 216 with split outputs reduces parasitic effects and ground bounce by dividing the current flow between multiple paths.

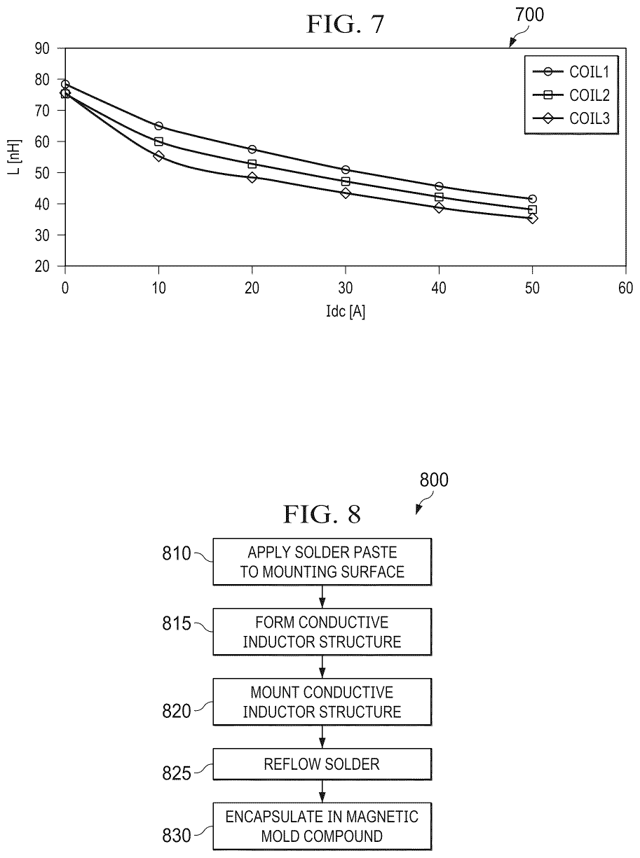

FIG. 7 illustrates an example of a graph 700 that plots inductance, in nanohenries (nH) as a function of direct current (DC) in amperes (A). The graph 700 includes a first plot (labeled “coil 1”) that corresponds to the inductor of the semiconductor package 100 of FIG. 1, with an inductance of about 2 milliohms (mΩ). The graph 700 include a second plot (labeled “coil 2”) that corresponds to the inductor of the semiconductor package 200 of FIG. 2 with an inductance of about 1.6 mΩ. The graph 700 also includes a third plot that corresponds to the inductor of the semiconductor package 300 of FIG. 3 with an inductance of about 1.8 mΩ. As is demonstrated by the graph 700, each example inductor has an inductance of at least about 35 mH at a current of about 50 A.

FIG. 8 illustrates a flowchart of an example method 800 for fabricating a semiconductor package, such as the semiconductor package 100 of FIG. 1. At block 810 solder is applied to selected locations on a mounting surface of an interconnect (e.g., interconnect 112 of FIG. 1).

At block 815, a conductive inductor structure is formed. Formation of the conductive inductor structure includes forming a first leg region (e.g., the first leg region 116 of FIG. 1) having a first bar (e.g., the first bar 124 of FIG. 1) extending orthogonally from a base and a first solderable member (e.g., the first solderable member 128 of FIG. 1) connected to the first bar and configured to extend parallel to the mounting surface. Formation of the conductive inductor structure also includes forming a second leg region (e.g., the second leg region 120 of FIG. 1) of the conductive inductor structure is formed such that the second leg region includes a second bar (e.g., the second bar 132 of FIG. 1) extending orthogonally from the base. The second leg structure also includes a second solderable member (e.g., the second solderable member 136 of FIG. 1) connected to the second bar and configured to extend parallel to the mounting surface. Formation of the conductive structure further includes forming a connecting bar (e.g., the connecting bar 144 of FIG. 1) between the first bar and the second bar.

In some examples, formation of the first leg region comprises forming a third bar (e.g., the second bar 226 of FIG. 2) parallel to the first bar (e.g., the first bar 224 of FIG. 2) and a first tying region (e.g., the first tying region 232 of FIG. 2) connecting the first bar and third bar and forming the second bar to be parallel to the connecting bar.

At block 820, the conductive inductor structure is mounted on the interconnect by placing the first solderable member and second solderable member in contact with the solder. At block 825, the solder applied to the interconnect is reflowed to form solder connections between the first solderable member and second solderable member and the interconnect. At block 830, the conductive inductor structure is encapsulated in a magnetic mold compound to form the inductor for the semiconductor package.

In this description, unless otherwise stated, “about” preceding a parameter means being within +/−10 percent of that parameter. Further, in this description, the term “couple”, “coupled” or “couples” means either an indirect or direct connection. Modifications are possible in the described embodiments, and other embodiments are possible, within the scope of the claims.

What is claimed is:

1. A semiconductor package comprising:
an interconnect having a mounting surface;
a conductive inductor structure mounted on the interconnect, the conductive inductor structure comprising:
a first leg region comprising:
a first bar extending orthogonally from the mounting surface to a given height; and
a first solderable member soldered to the mounting surface, the first solderable member is connected to the first bar and extends parallel to the mounting surface of the interconnect; and
a second leg comprising:
a second bar extending orthogonally from the mounting surface to the given height; and
a second solderable member soldered to the mounting surface, the second solderable member is connected to the second bar and extends parallel to the mounting surface of the interconnect;
a connecting bar extending at the given height between the first bar of the first leg region and the second bar of second leg region; and
a magnetic mold compound encasing the conductive inductor structure, wherein the magnetic mold compound and the conductive inductor structure form an inductor.

2. The semiconductor package of claim 1, wherein the connecting bar extends over at least one circuit component mounted on the interconnect.

3. The semiconductor package of claim 1, wherein the first solderable member and the second solderable member each have a solderable area of at least 0.9 square millimeters.

4. The semiconductor package of claim 1, wherein the first leg region further comprises:
a third bar extending orthogonally from the mounting surface to the given height, wherein the first bar and the third bar are parallel;
a tying region that extends parallel to the mounting surface of the interconnect at the given height, the tying region connecting the first bar, the third bar and the connecting bar of the conductive inductor structure; and
a third solderable member soldered to the mounting surface, the third solderable member is connected to the third bar and extends parallel to the mounting surface of the interconnect, and the third solderable member is spaced apart from the first solderable member.

5. The semiconductor package of claim 4, wherein the first leg region has a C-shaped cross-section.

6. The semiconductor package of claim 4, wherein the first leg region has an inverted U-shaped cross-section.

7. The semiconductor package of claim 4, wherein the second solderable member extends parallel to the connecting bar.

8. The semiconductor package of claim 4, wherein the first solderable member, the second solderable member and the third solderable member are configured to provide a butterfly structure having split outputs for the inductor.

9. The semiconductor package of claim 4, wherein the tying region is a first tying region, and the second leg region further comprises:
a fourth bar extending orthogonally from the mounting surface to the given height, wherein the second bar and the fourth bar are parallel;
a second tying region that extends parallel to the mounting surface of the interconnect at the given height, the second tying region connecting the second bar, the fourth bar and the connecting bar of the conductive inductor structure; and
a fourth solderable member soldered to the mounting surface, the fourth solderable member is connected to the fourth bar and extends parallel to the mounting surface of the interconnect, and the fourth solderable member is spaced apart from the second solderable member.

10. The semiconductor package of claim 1, wherein the first leg region and second leg region are symmetrically arranged on opposite sides of a center axis of the connecting bar.

11. The semiconductor package of claim 1, wherein the connecting bar has a length between about 5 millimeters and about 10 millimeters.

12. The semiconductor package of claim 1, wherein the first solderable member and the second solderable member each comprise a rectangular contact surface.

13. The semiconductor package of claim 1, wherein the first bar and second bar are parallel to each other.

14. The semiconductor package of claim 1, wherein:
the first leg region further comprises a first tying region that extends parallel to the mounting surface of the interconnect at the given height, the first tying region connecting the first bar and the connecting bar of the conductive inductor structure; and
the second leg region further comprises a second tying region that extends parallel to the mounting surface of the interconnect at the given height, the second tying region connecting the second bar and the connecting bar of the conductive inductor structure.

15. The semiconductor package of claim 1, wherein the first leg region and second leg region are asymmetrically arranged on opposite sides of a center axis of the connecting bar.

16. The semiconductor package of claim 1, wherein the first solderable member and the second solderable member are sized to maintain a current density below a predetermined threshold to reduce electromigration.

17. The semiconductor package of claim 1, wherein the conductive inductor structure has a resistance of 2 milliohms or less.

18. The semiconductor package of claim 1, wherein the inductor provides an inductance of at least 30 millihenries.

19. A method of fabricating a semiconductor package, the method comprising:
applying solder to selected locations on a mounting surface of an interconnect;
forming a conductive inductor structure comprising:
forming a first leg region having:
a first bar extending orthogonally from a base; and
a first solderable member connected to the first bar and configured to extend parallel to the mounting surface; and
forming a second leg region having:
a second bar extending orthogonally from the base;
a second solderable member connected to the second bar and configured to extend parallel to the mounting surface; and
forming a connecting bar between the first bar and the second bar;
mounting the conductive inductor structure on the interconnect by placing the first solderable member and second solderable member in contact with the solder;
reflowing the solder to form solder connections between the first solderable member and second solderable member and the interconnect; and
encapsulating the conductive inductor structure in a magnetic mold compound to form an inductor.

20. The method of claim 19, wherein:
forming the first leg region comprises forming a third bar parallel to the first bar and a first tying region connecting the first bar and third bar; and
forming the second bar to be parallel to the connecting bar.
